(19) United States
(12) Patent Application Publication
(10) Pub. No.: US 2006/0194075 A1
(43) Pub. Date: Aug. 31, 2006

(54) Light emitting element, light emitting device, and electronic apparatus

(75) Inventors: Tsutomu Miyamoto, Shiojiri-shi (JP); Yuji Fujimori, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/356,285

(22) Filed: Feb. 17, 2006

(30) Foreign Application Priority Data
Feb. 25, 2005 (JP) 2005-051980

(51) Int. Cl. H01L 51/50; H05B 33/00

(52) U.S. Cl. 428/690; 428/917; 428/304.4; 428/316.6; 313/504; 313/506

(57) ABSTRACT

A light emitting element comprises a first electrode, a second electrode, an emissive layer provided between the first electrode and the second electrode, and a carrier transporting layer provided between the first electrode and the second electrode, wherein the carrier transporting layer includes an electrolytic composition.

### 1. TECHNICAL FIELD

The present invention relates to a light emitting element, a light emitting device, and an electronic apparatus.

### 2. RELATED ART

With an organic electroluminescent (EL) element (light emitting element), which has a structure in which at least one luminescent organic layer (organic electroluminescent layer) is sandwiched between a cathode and an anode, an applied voltage can substantially be reduced compared to an inorganic EL element, and therefore an element having various luminescent colors can be manufactured. For reference, see Appl. Phys. Lett. 51 (12), 21 Sep. 1987, p. 913; Appl. Phys. Lett. 71 (1), 7 Jul. 1997, p. 34; Nature 357,477 1992; and JP-A-10-153967, JP-A-10-12377, and JP-A-11-40358, which are examples of related art.

At present, in order to obtain a higher performance organic EL element, material development and improvement as well as various device structures are being suggested and active researches are being conducted.

As for the organic EL element, an element having various luminescent colors and an element having a high brightness as well as a high efficiency have already been developed. A wide variety of practical applications such as utilization of a light emitting device as a pixel or a light source have been discussed.

Various studies are being conducted for practical applications, aimed at further improvement of the luminous efficiency.

### SUMMARY

An advantage of some aspects of the present invention is to provide a light emitting element that is excellent in luminous efficiency, and a light emitting device and an electronic apparatus that include the light emitting element and are high reliable.

The above advantage is attained by the following.

A light emitting element according to an aspect of the invention includes a first electrode, a second electrode, an emissive layer provided between the first electrode and the second electrode, and a carrier disporting layer provided between the first electrode and the second electrode, wherein the carrier transporting layer includes an electrolytic composition.

Thus a light emitting element excellent in luminous efficiency can be obtained.

In the above light emitting element, it is preferable that the electrolytic composition be in a liquid or gel state.

This can increase a contact area between the carrier transporting layer and the emissive layer. As a result the luminous efficiency of the light emitting element can be improved.

In the above light emitting element it is preferable that the electrolytic composition contain a I/I₃-based electrolyte.

In this electrolyte, oxidation-reduction reaction efficiently takes place. A region containing this electrolyte is therefore particularly excellent in hole transferring properties.

In the above light emitting element, it is preferable that the carrier transporting layer include a hole transfer layer and an electron transport layer, and that the first electrode, the hole transfer layer, the emissive layer, the electron transport layer, and the second electrode be deposited in this order.

This makes it possible to further improve the luminous efficiency of the light emitting element.

In the above light emitting element it is preferable that the hole transfer layer have at the side of the first electrode a second region mainly made of a polymer material.

Thus, a region mainly made of an electrolytic composition (hereinafter referred to as “first region”) can be prevented from coming in contact directly with the anode, and holes can be effectively injected into the first region. The provision of the second region can further improve the luminous efficiency of the light emitting element.

In the above light emitting element, it is preferable that the second region be in contact with the first electrode.

This can reliably prevent an increase in size (particularly an increase in film thickness) of the light emitting element and the reduction of the efficiency of injecting holes to the first region.

In the above light emitting element, it is preferable that the second region be in contact with a region made of the electrolytic composition as the main material.

This can reliably prevent an increase in size (particularly an increase in film thickness) of the light emitting element and the reduction of the efficiency of injecting holes to the first region.

In the above light emitting element, it is preferable that the polymer material contain a polythiophene-based compound.

Thus the efficiency of injecting holes to the first region can further be improved. As a result, the efficiency of transferring holes in the whole hole transfer layer is further improved.

In the above light emitting element, it is preferable that the hole transfer layer have an average thickness of 0.1 to 100 μm.

This allows a sufficient luminous efficiency to be obtained while preventing an increase in size (particularly an increase in film thickness).

In the above light emitting element, it is preferable that the electron transport layer be porous.

This porous electron transport layer can increase the formation region for an emissive layer. Namely, it can increase an amount of adhesion (adsorption amount) of a light emitting material to the electron transport layer. The hole transfer layer can also be formed so as to go into pores of the electron transport layer.

Accordingly, the contact area between the emissive layer and either the electron transport layer or the hole transfer layer increases so that the probability of recombination of holes and electrons can be increased. As a result, the luminous efficiency of the light emitting element is improved.

The light emitting sites expand, and therefore the carrier densities in light emitting materials can be reduced to moderate the speeds (the degrees) of deterioration and degradation of the light emitting materials. Namely, the durability (the lifetime) of the light emitting element can be improved.

It is preferable that the above light emitting element further include an intermediate layer between the electron transport layer and the second electrode.

Thus, a short circuit occurring with time in the light emitting element to reduce the luminous efficiency can be prevented. Namely the durability (the lifetime) can be improved.

In the above light emitting element it is preferable that the intermediate layer be formed so as to have a porosity smaller than that of the electron transport layer.

By the formation of this intermediate layer, the hole transfer layer can be more reliably prevented or restrained from being in contact with the cathode. The intermediate layer 8 having such a structure is advantageous because it can be formed with relative ease.

In the above light emitting element, assuming that the porosities of the intermediate layer and the electron transport layer are A [%] and B [%], respectively, it is preferable that B/A be equal to or greater than 1.1.

Accordingly, this relationship between the porosities can more reliably prevent or restrain the contact between the hole transfer layer and the cathode.

In the above light emitting element, it is preferable that the intermediate layer have a porosity equal to or less than 20%.

This porosity can further improve the effect of preventing or restraining the contact between the hole transfer layer and the cathode.

In the above light emitting element, it is preferable that the thickness ratio between the intermediate layer and the electron transport layer range from 1:99 to 60:40.

Thus, the intermediate layer can more reliably prevent or restrain the contact between the hole transfer layer and the cathode.

In the above light emitting element, it is preferable that the intermediate layer have an average thickness equal to or less than 1 μm.

This average thickness can further improve the effect of preventing or restraining the contact between the hole transfer layer and the cathode.

In the above light emitting element, it is preferable that the intermediate layer have electrical conductivity equivalent to that of the electron transport layer.

This allows the intermediate layer and the election transport layer to smoothly deliver and receive electrons.

In the above light emitting element, it is preferable that the intermediate layer be formed by an metal deposition (or decomposition method (hereinafter referred to as an “MOD method”).

The MOD method prevents the precursor of a constituent material of the intermediate layer from reading (such as hydrolyzing or condensation polymerizing) in an intermediate layer formation material. The intermediate layer can thereby be formed more easily and reliably (with good repeatability). The obtained intermediate layer can be made dense (having a porosity within the range mentioned above).

In the above light emitting element it is preferable that the resistance of the whole consisting of the intermediate layer and the electron transport layer in the thickness diction be equal to or more than 100 Ω/cm².

Thus, a leakage (a short circuit between the hole transfer layer and the electrode can more reliably be prevented or restrained. As a result, the durability (lifetime) of the light emitting element can further be improved.

In the above light emitting element it is preferable that the intermediate layer be positioned between the cathode and the electron transport layer.

Positioning the intermediate layer in this manner can more reliably prevent or restrain the contact between the hole transfer layer and the cathode.

In the above light emitting element it is preferable that the interface between the intermediate layer and electron transport layer be indefinite.

This allows the delivery and receipt of electrons between the intermediate layer and the election transport layer to be performed more reliably (efficiently).

In the above light emitting element, it is preferable that the intermediate layer and the electron transport layer be formed integrally.

This allows the delivery and receipt of electrons between the intermediate layer and the electron transport layer to be performed more reliably (efficiently).

It is preferable that part of the electron transport layer function as the intermediate layer.

This allows the delivery and receipt of electrons between the intermediate layer and the electron transport layer to be performed more reliably (efficiently).

In the above light emitting element it is preferable that the electron transport layer have a porosity of 20 to 75%.

This high porosity can adhere a larger amount of light emitting material to the electron transport layer 4 while preventing the reduction of mechanical strength of the electron transport layer, and also allows the hole transfer layer to go deep into the inside of the electron transport layer.

In the above light emitting element, it is preferable that the electron transport layer have an average thickness of 1 to 50 μm.

Such an average thickness can cause the light emitting element to be made thinner while preventing the reduction of mechanic strength (film strengthen) of the electron transport layer.

In the above light emitting element, it is preferable that the electron transport layer be made of an inorganic semiconductor material as its main material.

Because an inorganic semiconductor material is chemically stable, the use of an inorganic semiconductor material as the main material of the electron transport layer 4 further improves the durability of the light emitting element.

In the above light emitting element, it is preferable that the inorganic semiconductor material contain a metallic oxide as its main element.

The metallic oxide is preferred because it is particularly excellent in electron transferring properties.

In the above light emitting element, it is preferable that the inorganic semiconductor material contain at least one of titanium oxide and zirconium oxide as its main element.

In particular titanium oxide and zirconium oxide are preferred because they are particularly excellent in electron transferring properties.

In the above light emitting element, it is preferable that if the cathode 3 is made positive and the anode 6 is made negative and then a 0.5 V voltage is applied to the light emitting element, the light emitting element have such characteristics that the resistance is equal to or more than 100 Ω/cm².

Such characteristics show that a short circuit (leakage) between the cathode and the anode 6 is suitably prevented or restrained in the light emitting element. The light emitting element having these characteristics has a particularly high luminous efficiency.

Another aspect of the invention is directed to a light emitting device that includes the light emitting element of one aspect of the invention.

Thus, a light emitting device with high reliability can be obtained

A further aspect of the invention is directed to an electronic apparatus that includes the light emitting device of one aspect of the invention.

Thus, an electronic apparatus with high reliability can be obtained.

### BRIEF DESCRIPTION OF THE DRAWINGS

The invention will be described with reference to the accompanying drawings, wherein like numbers refer to like elements.

FIG. 1 is a view schematically showing a longitudinal section of an embodiment of a light emitting element of the invention.

FIG. 2 is an enlarged view showing the vicinities of interfaces of parts (layers) in the light emitting element shown in FIG. 1.

FIG. 3 is a further enlarged view showing the vicinity of interfaces of an electron transport layer, an emissive layer, and a hole transfer layer in the light emitting element shown in FIG. 1.

FIG. 4 is a longitudinal sectional view showing an embodiment of a display device to which a light emitting device of the invention is applied.

FIG. 5 is a perspective view showing the layout of a mobile type (or laptop type) personal computer to which an electronic apparatus of the invention is applied.

FIG. 6 is a perspective view showing the layout of a cellular phone (including a PHS) to which an electronic apparatus of the invention is applied.

FIG. 7 is a perspective view showing the layout of a digital still camera to which an electronic apparatus of the invention is applied.

### DESCRIPTION OF THE EMBODIMENT

In the following, a light emitting element, a light emitting device, and an electronic apparatus according to the invention will be described based on the preferred embodiment shown in the accompanying drawings.

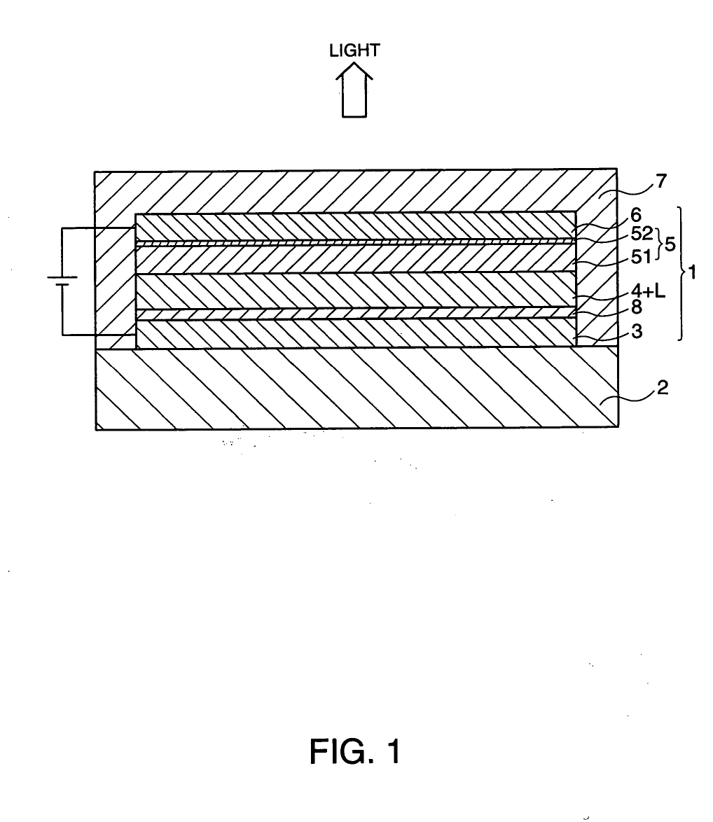

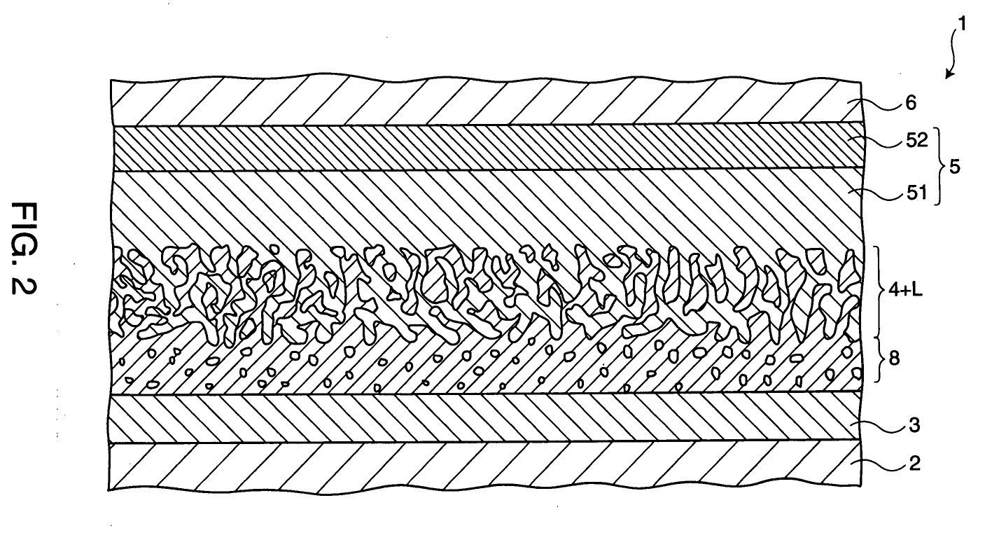

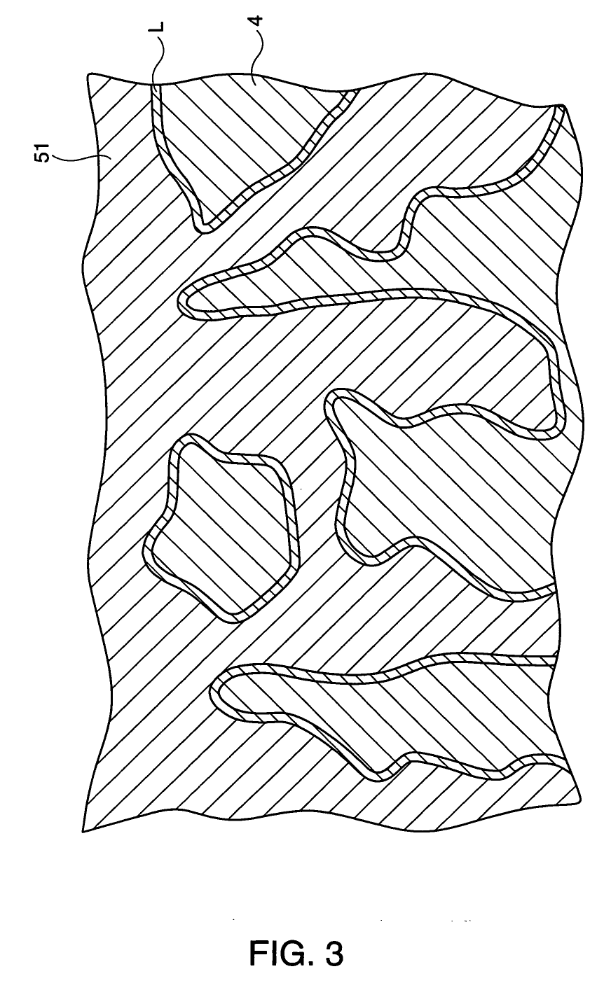

FIG. 1 is a view schematically showing a longitudinal section of an embodiment of a light emitting element of the invention. FIG. 2 is an enlarged view showing the vicinities of interfaces of parts (layers) in the light emitting element shown in FIG. 1. FIG. 3 is a more enlarge view showing the vicinity of interfaces of an electron transport layer, an emissive layer, and a hole transfer layer in the light emitting element shown in FIG. 1. Hereinafter, the upper sides of FIGS. 1 to 3 will be referred to as “upper” and their lower sides as “lower” for ease of explanation.

A light emitting element (an EL element) 1 shown in FIG. 1 includes a cathode (second electrode) 3 and an anode (first electrode) 6; an electron transport layer 4, an emissive layer L, and a hole transfer layer 5 interposed between the cathode 3 and anode 6; and an intermediate layer 8 further provided between the electron transport layer 4 and cathode 3. The whole light emitting element 1 is provided on a substrate 2, being sealed with a sealing member 7.

The substrate 2 serves as a base of the light emitting element 1. Since the light emitting element 1 according to the present embodiment has such a structure that light is extracted from the side opposite to the substrate 2 (top-emission type), neither the substrate 2 nor the cathode 3 particularly calls for transparency.

Examples of a substrate that can be used as the substrate 2 include: a transparent substrate made of a resin material such as poly(ethylene teraphthalate), poly(ethylene naphthalate), polypropylene, cycloolefin polymer, polyamide, polyethersulfone, poly(methyl methacrylate), polycarbonate, or polyalylate, or made of a glass material such as quartz glass or soda glass; a substrate made of a ceramic material such as alumina; a substrate made of metal such as stainless steel having an oxide film (insulating film) formed on its surface; and an opaque substrate made of an opaque resin material.

The average thickness of such the substrate 2 is not particularly limited, but is preferably about 0.1 to 30 nm, and more preferably about 0.1 to 10 nm.

In the structure of the light emitting element 1 in which light is extracted from the side of the substrate 2 (bottom emission type), the substrate 2 and the cathode 3 are made substantially transparent (transparent and colorless, transparent and colored, or translucent).

The cathode 3 is an electrode that injects electrons into the election transport layer 4 described later. It is preferable to use a material with a small work function as the constituent material of the cathode 3.

As the constituent material of the cathode 3, for example, Li, Mg, Ca, Sr, La, Ce, Er, Eu, Sc, Y, Yb, Ag, Cu, Al, Cs, Rb, and alloys containing these metals can be mentioned. These substances may be used singly or in combination of two or more kinds thereof (e.g. a deposited layer body having a plurality of layers).

Particularly if an alloy is used as the constituent material of the cathode 3, it is preferable to use an alloy containing a stable metal element such as Ag, Al, or Cu, and specifically an alloy such as MgAg, AlLi, or CuLi. Using such an alloy as the constituent material of the cathode 3 can improve the efficiency and stability of electron injection of the cathode 3.

The average thickness of the cathode 3 made by using such an alley is not particularly limited, but is preferably about 100 to 10000 nm, and more preferably about 200 to 500 nm.

The lower is the surface resistance of the cathode 3, the more preferable it is. Specifically, the surface resistance is preferably equal to or less than 50 Ω/cm², and more preferably 20 Ω/cm². The lower limit of the surface resistance is not particularly limited, but is preferable to be usually about 0.1 Ω/cm².

The anode 6 is an electrode that injects holes into the hole transfer layer 5 described later. It is preferable to use a material having a large work function as well as excellent conductivity as the constituent material of the cathode 3.

As the constituent material of the anode 6, for example, oxides such as indium tin oxide (ITO), indium zinc oxide (IZO), In₃O₃, SnO₂, and Al-containing ZnO; and Au, Pt, Ag, and Cu and alloys containing these metals can be mentioned. These substances may be used singly or in combination of two or more kinds thereof.

The average thickness of the cathode 3 made by using such a material is not particularly limited, but is preferably about 10 to 200 nm, and more preferably about 50 to 150 nm.

The lower is the surface resistance of the anode 6, the more preferable it is. Specifically, the surface resistance is preferably equal to or less than 100 Ω/cm², and more preferably 50 Ω/cm². The lower limit of the surface resistance is not particularly limited, but is preferable to be usually about 0.1 Ω/cm².

The electron transport layer 4 has a function to transport electrons injected from the cathode 3 to the emissive layer L.

The electron disport layer 4 may be dense, but is preferably porous as shown in FIGS. 2 and 3.

Thus, a region for forming the emissive layer L, which will be described later, can be increased. Namely, the amount of adhesion (the adsorption amount of a light emitting material to the electron transport layer 4 can be increased. The hole transfer layer 5 described later can also be formed so as to go into pores of the electron transport layer 4.

According the contact area between the emissive layer L and either the electron transport layer 4 or the hole transfer layer 5 increases so that the probability of recombination of holes and electrons can be increased. As a result, the luminous efficiency of the light emitting element 1 improves.

Thus light emitting sites expand, and therefore the carrier densities in light emitting materials can be reduced to moderate the speeds (the degrees) of deterioration and degradation of the light emitting materials. Namely, the durability (the lifetime) of the light emitting element 1 can be improved.

It is preferable that the electron transport layer 4 have the porosity as high as possible unless its mechanical strength (film strength) is not significantly reduced. Specifically, the porosity is preferably about 20 to 75%, and more preferably about 35 to 60%. Such a high porosity can adhere a larger amount of light emitting material to the electron transport layer 4 while preventing the mechanical strength of the electron transport layer 4 from being reduced. As a result of the high porosity, the hole transfer layer 5 can also be arranged deep into the election transport layer 4.

The electron transport layer 4 can be made of various n-type inorganic semiconductor materials or various n-type organic semiconductor materials, but is preferably made of an inorganic semiconductor material as the main material. Because inorganic semiconductor materials are chemically stable, the use of an inorganic semiconductor material as the main material of the electron transport layer 4 further improves the durability of the light emitting element 1.

Examples of the inorganic semiconductor materials include: metallic oxides such as titanium oxide (TiO₂), zirconium oxide (ZrO₂), zinc oxide (ZnO), aluminum oxide (Al₂O₃), tin oxide (SnO₂), ScVO₄, YVO₄, LaVO₄, NdVO₄, EuVO₄, GdVO₄, ScNbO₄, ScTaO₄, YNbO₄, YTaO₄, ScPO₄, ScAsO₄, ScSbO₄, ScBiO₄, YPO₄, YSbO₄, BVO₄, AlVO₄, GaVO₄, InVO₄, TIVO₄, InNbO₄, InTaO₄; metallic sulfides such as ZnS and CdS; metallic selenides such as CdSe; metallic or semiconductor carbides such as TiC and SiC; and semiconductor nitrides such as BN and B₄N. These materials may be used singly or in combination of two or more kinds thereof.

Among these materials, an inorganic semiconductor material containing a metallic oxide, particularly at least either of titanium oxide or zirconium oxide, as its main element is preferable. The metallic oxides (particularly titanium oxide and zirconium oxide) are particularly preferable because they are excellent in electron transferring properties.

Examples of the organic semiconductor materials include: benzene-based compounds such as 1,3,5-tris[(3-phenyl-6-tri-fluoromethyl)quinoxaline-2-yl]benzene (TPQ1) and 1,3,5-tris[{3-(4-t-butylphenyl)-6-trisfluoromethyl}quinoxaline-2-yl]benzene (TPQ2); metallic or non-metallic phthalocyanine-based compounds such as phthalocyanine, copper phthalocyanine (CuPc), and iron phthalocyanine; low molecular based materials such as tris(8-hydroxyquinolinolate)aluminium (Alq₃); and polymer-based materials such as oxadiazole-based polymers and triazole-based polymers.

The average thickness of the electron transport layer 4 made by using such a material is not particularly limited, but is preferably about 1 to 50 μm and more preferably about 5 to 30 μm. Such an average thickness can cause the light emitting element 1 to be made thinner while preventing the mechanical strength (film strength) of the electron transport layer 4 from decreasing.

In the election transport layer 4, the emissive layer light emitting parts) L is formed along the external surface of the electron transport layer 4 and internal surfaces of pores as shown in FIG. 3.

In the emissive layer L, electrons transported through the electron transport layer 4 and holes transferred through the hole transfer layer 5 described later recombine, generating excitons. When the excitons return to the ground state, energy (fluorescence or phosphorescence) is emitted. Namely the emissive layer L emits light.

As a constituent material of the emissive layer L as described above (light emitting material), various polymer light emitting materials and various low molecular light emitting materials may be used singly or in combination of any two or more kinds thereof.

Examples of the polymer light emitting materials include: polyacetylene-based compounds such as trans-polyacetylene, cis-polyacetylene, poly(di-phenylacetylene) (PDPA), and poly(alkyl, phenylacetylene) (PAPA); polyparaphenylenevinylene-based compounds such as poly(para-phenylenevinylene) (PV), poly(2,5-dialkoxy-para-phenylenevinylene) (RO-PPV), cyano-substituted-poly(para-phenylenevinylene) (CN-PPV), poly-(2-dimethyloctylsilyl-para-phenylenevinylene) (DMOS-PPV), and poly(2-methoxy-5-(2′-ethylhexoxy)-para-phenylenevinylene) (MEH-PPV); polythiophene-based compounds such as poly(3-alkylthiophene) (PAT) and poly(oxypropylene)triol (POPT); polyfluorene-based compounds such as poly(9,9-dialkylfluorene) (PDAF), poly(dioctylfluorene-alt-benzothiadiazole) (F8BT) (α, ω-bis[N,N-di(methylphenyl)aminophenyl]-poly(9,9-bis(2-ethylhexy)fluoren-2,7-diyl) (PF2/6am4), and poly[9,9-dioctyl-divinylenefluorenylene-ortho]-co-(anthracene-9,10-dily); polyparaphenylene-based compounds such as poly(para-phenylene) (PPP), and poly(1,5-dialkoxy-para-phenylene) (RO-PPP); polycarbazole-based compounds such as poly(N-vinylcarbazole) (PVK); and polysilane-based compounds such as poly(methylphenylsilane) (PMPS), poly(naphthylphenylsilane) (PNPS), and poly(biphenylylphenylsilane) (PBPS).

Examples of the low-molecular light emitting materials include: various metal complexes such as iridium complex having 2,2′-bipyridine-4,4′-dicarboxylic acid as its ligand, factris(2-phenylpyridine) iridium (Ir(ppy)₃), 8-hydroxyquinoline aluminum (Alq₃), tris(4-methyl-8quinolinolate) aluminum(III)(Almq₃), 8-hydroxyquinoline zinc (Znq₂), (1,10-phenanthroline)-tris-(4,4,4-trifluoro-1-(2-thienyl)-butane-1,3-dionate)Europium(III); (Eu(TTA)₃(phen)), and 2,3,7,8,12,13,17,18-Octaethyl-21H,23H-porphine platinum(II); benzene-based compounds such as distyrylbenzene (DSB), and diaminodistyrylbenzene (DADSB); naphthalene-based compounds such as naphthalene and Nile red; phenanthrene-based compounds such as phenanthrene; chrysene-based compounds such as chrysene and 6-nitrochrysene; perylene-based compounds such as perylene and N,N′-bis(2,5-di-t-butylphenyl)-3,4,9,10-perylene-di-carboxyimide (BPPC); coronene-based compounds such as coronene; anthracene-based compounds such as anthracene and bisstyrylanthracene; pyrene-based compounds such as pyrene; pyran-based compounds such as 4-(di-cyanomethylene)-2-methyl-6-(para-dimethylaminostyryl)-4H-pyran (DCM); acridine-based compounds such as acridine; stilbene-based compounds such as stilbene; thiophene-based compounds such as 2,5-dibenzooxazolethiophene; benzooxazole-based compounds such as benzoxazole; benzoimidazole-based compounds such as benzoimidazole; benzothiazole-based compounds such as 2,2′-(para-phenylenedivinylene)-bisbenzothiazole; butadiene-based compounds such as bistyryl(1,4-diphenyl-1,3-butadiene), and tetraphenylbutadiene; naphthalimide-based compounds such as naphthalimide; coumarin-based compounds such as coumarin; perynone-based compounds such as perynone; oxadiazole-based compounds such as oxadiazole; aldazine-based compounds; cyclopentadiene-based compounds such as 1,2,3,4,5-pentaphenyl-1,3-cyclopentadiene (PPCP); quinacridone-based compounds such as quinacridone and quinacridone red; pyridine-based compounds such as pyrrolopyridine and thiadiazolopyridine; spiro compounds such as 2,2′,7,7′-tetraphenyl-9,9′-spirobifluorene; metallic or non-metallic phthalocyanine-based compounds such as phthalocyanine H₂Pc) and copper phthalocyanine; and florene-based compounds such as florene.

Among these materials, a material containing a metal complex as its main element is preferable as the constituent material of the emissive layer L. The light emitting material containing a metal complex as its main element is preferable because it adheres in large quantity to an inorganic semiconductor material with relative ease and is excellent in luminescence properties.

The amount of adhesion of such a light emitting material to the electron transport layer 4 is not particularly limited, but is preferably about 1×10⁻⁹ to 10⁻⁶ mol, and more preferably about 1×10⁻⁸ to 10₋₇ mol. Making such an amount of light emitting material adhere to the electron transport layer 4 can further improve the luminous efficiency of the light emitting element 1.

In addition, the light emitting material may not constitute a layer, but may adhere (be adsorbed) to the external surface of the electron transport layer 4 as well as the internal surfaces of pores so as to be scattered. In this structure, the whole consisting of the electron transport layer 4 and the light emitting material may be referred to as an emissive layer.

The hole transfer layer 5 is provided in contact with the emissive layer L as described above.

The hole transfer layer 5 has a function of transferring holes injected from the anode 6 to the emissive layer L.

The hole transfer layer 5 according to the embodiment includes a first region 51 at the side of the emissive layer L (at the side of the electron transport layer 4) and a second region 52 at the side of the anode 6.

The first region 51 is made by using an electrolytic composition as its main material. The electrolytic composition is excellent in transferring properties of holes. For this reason, forming part of the hole transfer layer 5 by using an electrolytic composition as its main material can improve the luminous efficiency of the light emitting element 1.

The electrolytic composition may be in a solid state, but is preferably in a liquid or gel state. Thus the electrolytic composition can be filled deeper into the internal of the electron transport layer 4, whereby the contact area between the hole transfer layer 5 and the emissive layer L can be further increased. As a result, the luminous efficiency of the light emitting element 1 can further be improved.

The electrolyte used for the electrolytic composition is not particularly limited; halogen-based sulks such as I/I₃-based, Br/Br₃-based, Cl/Cl₃-based, and F/F₃-based substances, and quinone/hydroquinone based substances, for example, may be used. These substances may be used singly or mixed together.

Among these chemicals, a I/I₃-based substance is preferable as the electrolyte. In this electrolyte, oxidation-reduction reaction efficiently takes place. The first region 51 containing this electrolyte is therefore particularly excellent in hole transferring properties.

As a specific example of the electrolyte made of a I/I₃-based substance, I₂ in combination with a metal iodide such as LiI, NaI, KI, CsI, or CaI₂ or in combination with iodine salt of a quaternary ammonium compound such as tetraalkylammonium iodide, pyridinium iodide, or imidazolium iodide can be mentioned.

Examples of solvents used for the electrolytic composition include: various water, nitriles such as acetonitrile, propionitrile, and benzonitrile; carbonates such as ethylene carbonate and propylene carbonate; polyhydric alcohols such as polyethylene glycol, polypropylene glycol and glycerin and propylene carbonate. These chemicals may be used as single solvents or mixed solvents. The electrolyte composition excellent in can conduction can be obtained by using these solvents.

The concentration of the whole electrolyte in the electrolytic composition is not particularly limited, but is preferably about 0.1 to 25 wt, and more preferably about 0.5 to 15 wt %.

It is also preferable to add basic compounds such as t-butylpyridine, 2 picoline, and 2,6-lutidine to the electrolyte composition.

Adding a polymer into an electrolytic composition (method I), adding an oil gelatinizing agent to an electrolytic composition (method II), adding a polymer precursor to an electrolytic composition to polymerize (method III), adding a polymer to an electrolytic composition to cause a cross-linking reaction (method IV), and other methods can pectize the electrolytic composition.

As the polymer used in the method I, thermoplastic resins such as polyethylene oxide (PEO), polyacrylonitrile (PAN), polyvinylidene fluoride (PVDF), and polymethyl methacrylate) (PMMA) can be mentioned. These polymers may be used singly or in combination of two or more kinds thereof.

Among these polymers, such a polymer that uses particularly at least either polyacrylonitrile or polyvinylidene fluoride as its main element is preferable.

As the oil gelatinizing agents used in the method II, compounds having an amide structure is preferably used.

As the polymer precursors used in the method III, precursors of various curing resins such as thermosetting resins, photosetting resins, and anaerobic curing resins can be mentioned.

In the method IV, it is preferable to use a polymer containing a reactive group conjunction together with a cross-linking agent causing a cross-linking reaction with the reactive group.

As the reactive group, for example, amino group, pyridine ring, imidazole ring, thiazole ring, oxazole ring, morpholine ring, piperidine ring, and piperazine ring can be mentioned.

As the cross-linking agent, for example, alkyl halides, aralkyl halides, ester of sulfonic acids, acid anhydrides, acid chlorides, isocyanate compounds, α,β-unsaturated sulfonyl compounds, α,β-unsaturated carbonyl compounds, and α,β-unsaturated nitrile compounds can be mentioned.

The second region 52 is a solid layer (or film) and has a function to prevent the first region 51 from coming in contact directly with the anode 6. The provision of the second region 52 as described can reduce the interface resistance between the hole transfer layer 5 and the anode 6, thereby allowing holes to be effectively injected into the first region 51. As a result, the luminous efficiency of the light emitting element 1 can be further improved.

As the constituent material of the second region 52, various p-type polymer materials and various p-type low-molecular materials may be used sing or in combination.

Examples of p-type polymer materials (organic polymers) include polyarylamine, fluorene arylamine copolymers, fluorene bithiophene copolymers, poly(N-vinylcarbazole), polyvinyl pyrene, polyvinyl anthracene, polythiophene, polyalkylthiophene, polyhexylthiophene, poly(p-phenylenevinylene), polythienylenevinylene, pyrene-formaldehyde resin, ethylcarbazole formaldehyde resin, and derivatives thereof.

The above compounds can also be used as their mixtures with other compounds. As an exemplary mixture containing polythiophene, poly(3,4-ethylenedioxythiophene/styrenesulfonic acid) (PEDOT/PSS) can be mentioned.

Examples of p-type low molecular materials include: arylcycloalkane-based compounds such as 1,1-bis(4-di-para-triaminophenyl)cyclohexane and 1,1′-bis(4-di-para-tolylaminophenyl)-4-phenyl-cyclohexane; arylamine-based compounds such as 4,4′,4″-trimethyltriphenylamine, N,N,N′,N′-etraphenyl-1,1′-biphenyl-4,4′-diamine, N,N′-diphenyl-N,N-bis(3-methylphenyl-1,1′-biphenyl-4,4′-diamine (TPD1), N,N′-diphenyl-N,N′-bis(4-methoxyphenyl)-1,1′-biphenyl-4,4′-diamine(TPD2), N,N,N′,N′-tetrakis(4-methoxyphenyl)-1,1′-biphenyl-4,4′-diamine (TPD3), N,N′-di(1-napthyl)-N,N′-diphenyl-1,1′-biphenyl-4,4′-diamine(α-NPD), and TPTE; phenylenediamine-based compounds such as N,N,N′,N′-tetraphenyl-para-phenylenediamine, N,N,N′,N′-tetra(para-tolyl)-para-phenylenediamine, and N,N,N′,N′-tetra(meta-tolyl)-meta-phenylenediamine (PDA); carbazole-based compounds such as carbazole, N-isopropylcarbazole, and N-phenylcarbazole; stilbene-based compounds such as stilbene and 4-di-para-tolylaminostilbene; oxazole-based compounds such as OₓZ; triphenylmethane-based compounds such as triphenylmethane and m-MTDATA; pyrazoline-based compounds such as 1-phenyl-3-(para-dimethylaminophenyl)pyrazoline; benzine(cyclohexadiene)-based compounds; triazole-based compounds such as triazole; imidazole-based compounds such as imidazole; oxadiazole-based compounds such as 1,3,4-oxadiazole and 2,5-di(4-dimethylaminophenyl)-1,3,4-oxadiazole; anthracene-based compounds such as anthracene and 9-(4-diethylaminostyryl)anthracene; fluorenone-based compounds such as fluorenone, 2,4,7-trinitro-9-fluorenone, and 2,7-bis(2-hydroxy-3-(2-chlorophenylcarbamoyl)-1-naphthylazo)fluorenone; aniline-based compounds such as polyaniline; silane-based compounds; pyrrole-based compounds such as 1,4-dithioketo-3,6-diphenyl-pyrrolo-(3,4-c)pyrrolopyrrole; florene-based compounds such as florene; porphyrin-based compounds such as porphyrin and metal tetraphenylporphyrin; quinacridon-based compounds such as quinacridon; metallic or non-metallic phthalocyanine-based compounds such as phthalocyanine, copper phthalocyanine, tetra(t-butyl)copper phthalocyanine, and iron phthalocyanine; metallic or non-metallic naphthalocyanine-based compounds such as copper naphthalocyanine, vanadyl naphthalocyanine, and monochloro gallium naphthalocyanine; and benzidine-based compounds such as N,N′-di(naphthalene-1-yl)-N,N′-diphenyl-benzidine and N,N,N′,N′-tetraphenylbenzidine.

Among these materials, the material primarily containing a polymer material is preferable as the constituent material of the second region 52. The second region 52 is formed by using a polymer material as the main material and thus is provided with the function of preventing the first region 51 from coming in contact with the anode 6 and function of improving the efficiency of injecting holes to the first region 51. As a result, the second region 52 can be made more excellent.

In particular, the material containing a polythiophene compound, particularly PEDOT/PSS mentioned above, is preferable as the constituent material of the second region 52. Thus the efficiency of injecting holes to the first region 51 can be more improved.

If the second region 52 is provided between the first region 51 and the anode 6, the effect mentioned above is fully realized. However, the second region 52 is preferably in contact with at least either the first region 51 or the anode 6, and more preferably in contact with both of them. Thus a size increase (particularly an increase of film thickness) of the light emitting element 1 and the reduction of the efficiency of injecting holes to the first region 51 can reliably be prevented.

The average this of the hole transfer layer 5 as described is not particularly limited, but is preferably about 0.1 to 100 μm, and more preferably about 1 to 30 μm. This allows a sufficient luminescence efficiency to be obtained while preventing a size increase (particularly an increase of the film thickness) of the light emitting element 1.

In addition, the second region 52 can be omitted as the need arises.

The sealing member 7 is disposed so as to cover the cathode 3, the electron transport layer 4 in which the emissive layer L is formed, the hole transfer layer 5, and the anode 6, and has the function of airtightly sealing them to block oxygen and moisture. The sealing member 7 provides effects such as improving reliability and preventing degradation and deterioration (durability improvement in the light emitting element 1.

As the constituent material of the sealing member 7, for example, Al, Au, Cr, Nb, Td, Ti, and alloys containing them, oxide silicon, various resin materials can be mentioned.

The sealing member 7 may be plate-shaped to face the substrate 2 such that the spacing between the sealing member 7 and substrate 2 is sealed with a sealing material made up of, for example, a thermosetting resin or the like.

In the light emitting element 1 as described above, the intermediate layer 8 is disposed between the electron transport layer 4 and the cathode 3.

The intermediate layer 8 may have the function to prevent holes injected from the anode 6 from reading the cathode 3, and may also have the function to slow the movement of electrons injected from the cathode 3 to the emissive layer L (the electron transport layer 4).

The intermediate layer 8 may have any structure, but is preferably formed so that the porosity of the intermediate layer 8 is smaller than that of the electron transport layer 4 as shown in FIG. 2. The intermediate layer 8 having such a stature can be formed with relative ease.

Assuming that the porosities of the intermediate layer and the electron transport layer are A [%] and B [%], respectively, B/A is preferably equal to or greater than 1.1, more preferably equal to or greater than 5, and further preferably equal to or greater than 10.

Specifically the porosity A [%] of the intermediate layer 8 is preferably equal to or less than 20%, more preferably equal to or less than 5%, and further preferably equal to or less than 2%. Namely the intermediate layer 8 is preferably a dense layer. The dense layer can further improve the effects mentioned above.

The thickness ratio between the intermediate layer 8 and the electron transport layer 4 is not particularly limited, but is preferably about 1:99 to 60:40, and more preferably 10:90 to 40:60. In other words, the thickness ratio of the intermediate layer 8 to the whole consisting of the intermediate layer 8 and the electron transport layer 4 is preferably about 1 to 60%, and more preferably about 10 to 40%.

Specifically the average thickness of the intermediate layer 8 is preferably equal to or less than 3 μm, and more preferably range from 0.1 to 1 μm or less. Such an average thickness can still further improve the effect mentioned above.

The constituent material of the intermediate layer 8 is not particularly limited; for example, various inorganic insulating materials such as SiO₂ and various organic insulating materials other than various semiconductor materials described for the election transport layer 4 may be used. Among them, the material having elect conductivity equivalent to that of the electron transport layer 4 is preferable, and particularly the material having the same composition as the electron transport layer 4 is more preferable. This allows the delivery and receipt of electrons between the intermediate layer 8 and electron transport layer 4 to be smoothly performed.

The resistances of the intermediate layer 8 and the electron transport layer 4 in the thickness direction are not particularly limited, but the resistance of the whole consisting of the intermediate layer 8 and the electron transport layer 4 in the thickness direction namely the of the deposited layer body consisting of the intermediate layer 8 and the electron transport layer 4 is preferably equal to or more than 100 Ω/cm², and more preferably equal to or more than 1 kΩ/cm². Thus, a leakage (short circuit between the hole transfer layer 5 and the cathode 3 can reliably be prevented or strained. As a result, further improvement of durability (lifetime) of the light emitting element 1 can be achieved.

The interface between the intermediate layer 8 and the electron transport layer 4 may be or may not be definite, but is preferably not definite (indefinite). Namely, it is preferable that the intermediate layer 8 and the electron transport layer 4 partially overlap with each other.

Furthermore, it is preferable that the intermediate layer 8 and the electron transport layer 4 be integrated as shown in FIG. 2, namely the intermediate layer 8 and the electron transport layer 4 be formed integrally. This allows the delivery and receipt of electrons between the intermediate layer 8 and the electron transport layer 4 to be performed more reliably (efficiently).

If the intermediate layer 8 is provided between the cathode 3 and the electron transport layer 4, the effect mentioned above is fully realized. However, the intermediate layer 8 is preferably in contact with at least either cathode 3 or the electron transport layer 4, and more preferably in contact with both of them. Thus a size increase (particularly an increase of film thinness) of the light emitting element 1 and the reduction of the efficiency of injecting electrons to the emissive layer L can reliably be prevented.

The position in which the intermediate layer 8 is placed is not limited to that shown in the drawings, but may be, for example, between the electron transport layer 4 and the emissive layer L.

A dense part and a sparse part may be provided in the direction of thickness of the electron transport layer 4 such that the dense part functions as the intermediate layer L.

In this case, an arbitrary number of dense parts can be provided at an arbitrary position in the direction of thickness of the electron transport layer 4. Specifically, the electron transport layer 4 may have a structure of having one dense part at the side of the cathode 3, a structure of having one dense part at the side of the emissive layer L, a structure of having a sparse part sandwiched by dense parts, a structure of having a dense part sandwiched by sparse parts, and other structures.

If when the cathode 3 is made positive and the anode 6 is made negative, a 0.5 V voltage is applied to the light emitting element 1, the light emitting element 1 preferably has the characteristics of having the resistance equal to or more than 100 Ω/cm², and more preferably has characteristics of having a resistance equal to or more than 100 Ω/cm². Such characteristics show that a short circuit leakage) between the cathode 3 and the anode 6 is suitably prevented or restrained in the light emitting element 1. The light emitting element 1 having the characteristics mention above has a particularly high luminous efficiency.

The light emitting element 1 as described above can be manufactured, for example, as follows.

1. Initially, the substrate 2 is provided, on which the cathode 3 is formed.

The anode 3 can be formed, for example, by chemical vapor deposition (CVD) such as plasma CVD, thermal CVD, or laser CVD; dry plating such as vacuum deposition, sputtering, or ion plating; vapor deposition such as thermal spraying; wet plating such as electrolytic plating, immersion plating, or electroless plating; a liquid phase film growth method such as a sol-gel method or a MOD method; bonding of a metallic foil, or the like.

2. Next the intermediate layer 8 is formed on the cathode 3.

The intermediate layer 8 may be formed, for example, by a sol-gel method, deposition (vacuum deposition) method, sputtering method (high frequency sputtering, DC sputtering), spray thermal decomposition method, jet-molding (plasma thermal spraying) method, CVD method, or the like. Among them, the intermediate layer 8 is preferably formed by the sol-gel method.

The sol-gel method is very easy to operate. The use of the sol-gel method allows a intermediate layer formation material for forming the intermediate layer 8 to be supplied, for example, by various coating methods such as a dipping method, falling drop method, doctor blade method, spin coating method, painting with brush, spray coating method, roll coating method, and other methods. The intermediate layer 8 having a desired film thickness can thereby be formed with relative ease without the need for large-scale facilities.

Particularly in order to form the intermediate layer 5, it is preferable to use an MOD method.

The MOD method prevents the reaction (such as hydrolysis, polycondensation) of the precursor of a constituent material of the intermediate layer 8 in an intermediate layer formation material. The intermediate layer 8 can thereby be formed more easily and reliably (with good repeatability). The intermediate layer 8 obtained can be made dense (having a porosity within the above range).

If the intermediate layer 8 is formed using titanium dioxide as its main material organic titanium compounds such as titanium tetraisopropoxide (TPT) or titanium tetramethoxide can be used as the precursor of titanium dioxide.

3. The electron transport layer 4 is then formed on the intermediate layer 8.

The electron transport layer 4 can be formed by supplying an electron transport layer formation material containing, for example, particles of the semiconductor material desired above onto the intermediate layer 5, and after removing the dispersion medium, baking the material.

The electron transport layer formation material may be prepared by adding the above particles to the sol liquid used in the sol-gel method of the above process 2.

Various coating methods as described above can be used as the method of supplying electron transport layer formation material.

4. The emissive layer L is formed so as to come in contact with the electron transport layer 4.

The emissive layer L can be formed, for example, by making a liquid containing a light emitting material in contact with the election transport layer 4 and then removing the solvent (removing the dispersion medium).

Thus, the light emitting material is, for example, adsorbed, bonded or the like to the external surface of the election transport layer 4 and internal surfaces of the pores, so that the emissive layer L is formed along these surfaces.

Examples of methods to make a liquid containing a light emitting material come in contact with the electron transport layer 4 include a method of dipping a deposited layer body consisting of the substrate 2, the cathode 3, the intermediate layer 5, and the electron transport layer 4, for example, into a liquid containing a light emitting material (dipping method), a method of coating a liquid containing a light emitting material to the electron transport layer 4 (coating method), and a method of supplying a liquid containing a light emitting material to the electron transport layer 4 in a shower-like manner.

Examples of the solvent (or dispersion medium) to prepare a liquid containing a light emitting material include various types of water, methanol ethanol isopropyl alcohol acetonitrile, ethyl acetate, ether, dichloromethane, N-methyl-2-pyrrolidone (NMP). These substances may be used in or in combination of two or more kinds thereof.

As the method of removing a solvent, for example, a method of leaving a solvent under atmospheric pressure or under reduced pressure, a method of spraying a gas such as air or a nitrogen gas, and the like can be mentioned.

In addition, heat treatment may be applied to the deposited layer body at a temperature of around 60 to 100° C. for around 0.5 to 2 hours, as the need arises. This allows a light emitting material to be adsorbed (bonded) to the electron transport layer 4 more solidly.

5. The anode 6 is formed on the inside top surface of the sealing member 7.

The anode 6 can be formed, for example, by a vacuum vapor deposition method, a sputtering method, bonding of a metallic foil, or the like.

6. Next the second region 52 is formed on the undersurface of the anode 6.

The second region 52 can be formed in a manner similar to the emissive layer L.

7. The sealing member 7 is then placed so as to cover the cathode 3 and the electron transport layer 4 in which the emissive layer L is formed, and is joined to the substrate 2.

8. An electrolytic composition is injected from an inlet (not shown) provided in the sealing member 7 to a space between the electron transport layer 4, in which the emissive layer L is formed, and the second region 52.

Subsequently, the inlet is sealed, for example, by a sealing material such as an adhesive agent.

The light emitting element 1 according to the invention is manufactured through the processes described above.

The light emitting element 1 as such can be used, for example, as a light source. A display device (light emitting device according to the invention can be formed by place a plurality of the light emitting elements 1 in a matrix.

In addition, the drive system of the display device is not particularly limited; either an active matrix system or a passive matrix system may be used.

An exemplary display device to which the light emitting device of the invention is applied will now be described.

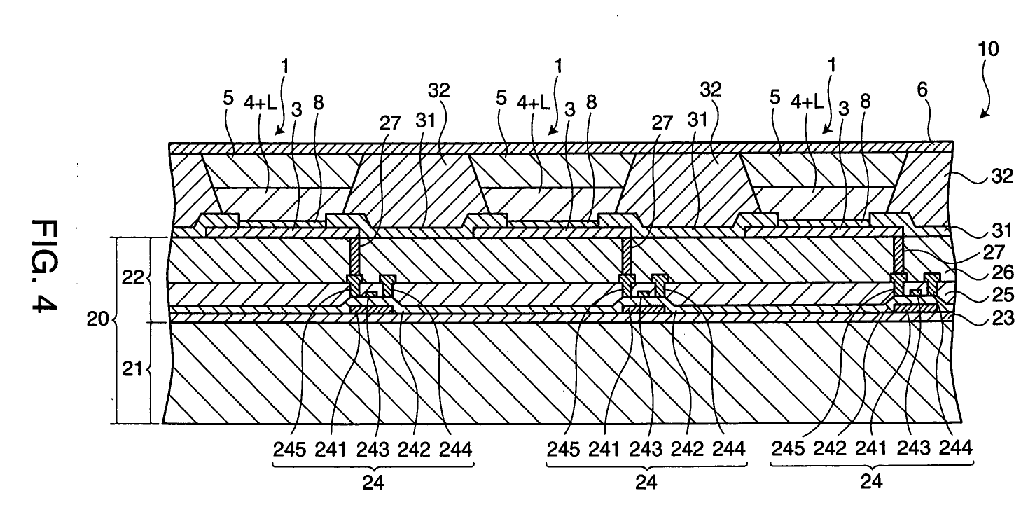

FIG. 4 is a longitudinal sectional view showing an embodiment of the display device to which a light emitting device of the invention is applied.

A display device 10 shown in FIG. 4 includes a base 20 and a plurality of light emitting element 1 disposed on the base 20.

The base 20 has a substrate 21 and a circuit section 22 formed on the substrate 21.

The circuit section 22 has a protective layer 23 constituted, for example, of a silicon oxide layer formed on the substrate 21, a driving TFT (switching element 24 formed on the protective layer 23, a first interlayer insulating layer 25, and a second interlayer insulating layer 26.

The driving TFT 24 has a semiconductor layer 241 made of silicon, a gate insulating layer 242 formed on the semiconductor layer 241, a gate electrode 243 formed on the gate insulting layer 242, a source electrode 244, and a drain electrode 245.

On the circuit section 22 as such, the light emitting element 1 is provided in correspondence to each driving TFT 24. The light emitting elements 1 adjacent one another are zoned by first dividing wall sections 31 and second dividing wall sections 32.

In the present embodiment, the cathode 3 of each light emitting element 1 constituting a pixel electrode is electrically connected to the dram electrode 245 of each driving TFT 24 by an interconnection 27. The anode 6 of each light emitting element 1 is a common electrode.

A sealing member (not shown) is joined to the base 20 so as to cover each of the light emitting element 1, sealing each of the light emitting element 1.

The display device 10 may display in monochrome, and can also display in color by choosing a light emitting material used for each of the light emitting element 1.

The display device 10 as such (light emitting device of the invention can be incorporated into various types of electronic apparatuses.

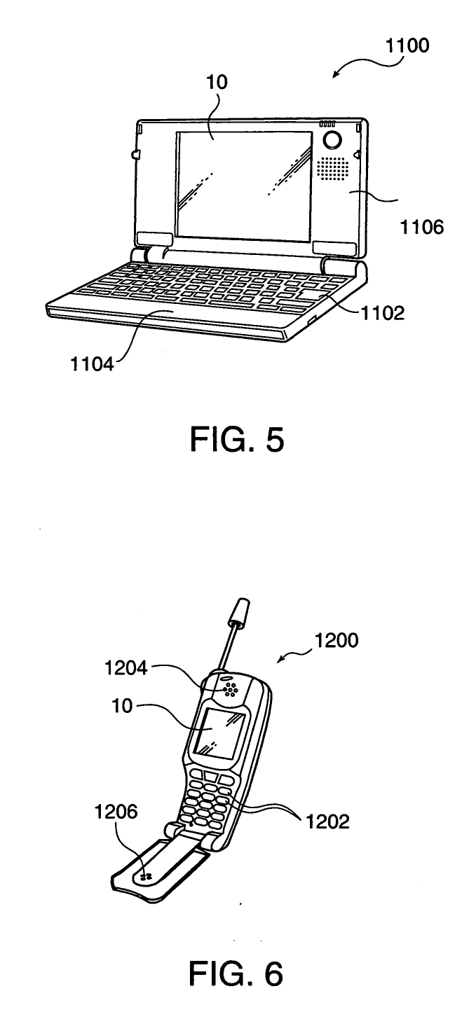

FIG. 5 is a perspective view showing the layout of a mobile type (or laptop type) personal computer to which an electronic apparatus of the invention is applied.

In the drawing, a personal computer 1100 includes a main body section 1104 with a keyboard 1102 and a display unit 1106 with a display section. The display unit 1106 is rotatably supported with respect to the main body section 1104 with a hinge portion.

In the personal computer 1100, a display section included in the display unit 1106 includes the display device 10 described above.

FIG. 6 is a perspective view showing the layout of a cellular phone (including a PHS) to which an electronic apparatus of the invention is applied

In the drawing, a cellular phone 1200 includes a plurality of operation buttons 1202, an earpiece 1204, and a mouthpiece 106 as well as a display section.

In the cellular phone 1200, the display section includes the display device 10 mentioned above.

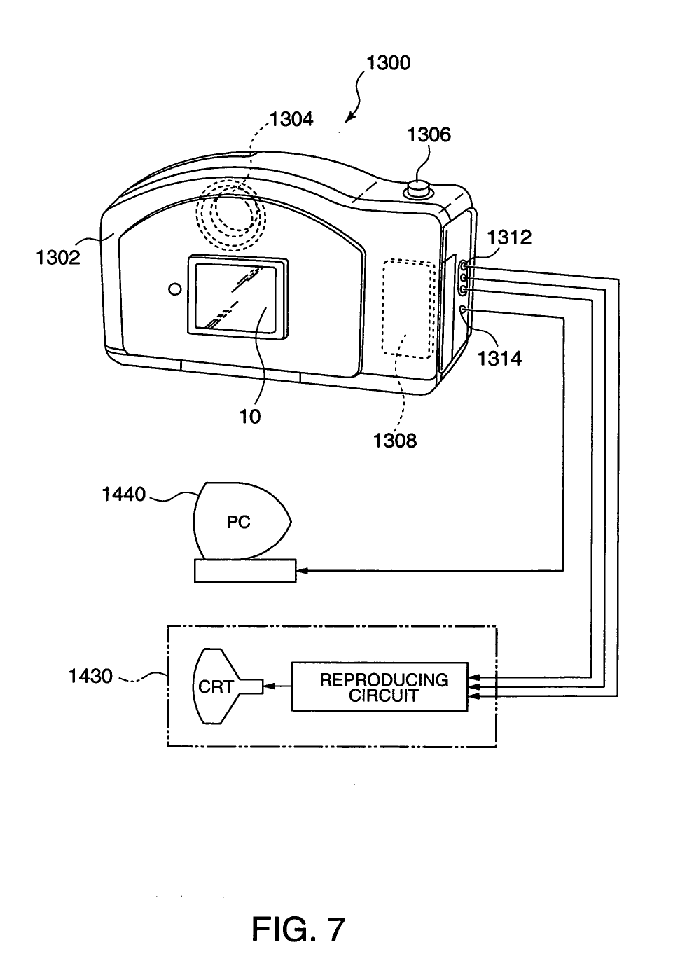

FIG. 7 is a perspective view showing the layout of a digital still camera to which an electronic apparatus of the invention is applied. In the drawing, connection to the external devices is also shown simply.

A normal camera exposes a silver halide photography film to light using the light figure of a target, whereas a digital still camera 1300 photoelectrically converts the light figure of a target by an image pickup element such as a charge coupled device (CCD) to generate pickup signals (picture signals).

A display section is provided on the back surface of a case (body) 1302 in a digital still camera 1300 such that the display is performed based on pickup signals generated by the CCD, functioning as a finder to display a target as an electron image.

In the digital still camera 1300, the display section includes the display device 10 described above.

A circuit board 1308 is disposed inside the case. In the circuit board 1308, memory into which pickup signals can be stored is provided.

A light receiving unit 1304 including an optical lens (image pickup optical system), a CCD, and the like is provided on the front side of the case 1302 (back side in the layout of the drawing).

When a photographer confirms a target image displayed on the display section and holds down a shutter button 1306, pickup signals in the CCD at this point is transferred and stored into memory of the circuit board 1308.

In the digital still camera 1300, a video signal output terminal 1312 and a data communication I/O terminal 1314 are provided on the side surface of the case 1302. As shown in the drawing, a television monitor 1430 is connected to the video signal output terminal 1312, and a personal computer 1440 to the data communication I/O terminal 1314, respectively, if required. Furthermore, the digital still camera 1300 is structured such that pickup signals stored in the memory of the circuit board 1308 are output to the television monitor 1430 and the personal computer 1440.

The electronic apparatus of the invention may be applied, for example, to a television set, video camera, viewfinder type or monitor-direct-view-type video tape recorder, laptop type personal computer, car navigation device, pager, electronic organizer (including one with communication function), electronic dictionary electronic calculator, computerized game apparatus, word processor, workstation, television telephone, security television monitor, electronic binoculars, POS terminal device with a touch panel (e.g. cash dispenser of a financial institution, automatic ticket machine), medical instrument (e.g. electronic thermometer, blood pressure manometer, blood glucose meter, electrocardiograph, ultrasonograph, endoscope display device), various measuring instruments, gauges (e.g. gauges for vehicles, airgrafts, and vessels), a flight simulator, other various monitors, projection type display devices such as a projector, etc., other than the personal computer (mobile type personal computer) of FIG. 5, the cellular phone of FIG. 6, and the digital still camera of FIG. 7.

It is to be understood that the light emitting element, the light emitting device, and the electronic apparatus of the invention have been described based on the embodiment shown in the drawings but the invention is not limited thereto.

### EXAMPLES

The specific examples of the invention will now be described.

1. Manufacturing of Light Emitting Element

### Example 1

[1] Initially, two transparent glass substrates with an average thickness of 0.5 mm were prepared.

[2] AlLi was adhered onto one glass substrate by a vacuum vapor deposition method, thereby forming a cathode with an average thickness of 300 nm. The surface resistance of the cathode was about 5 Ω/□.

[3] A titanium oxide (TiO₂) was adhered onto the cathode by a vacuum vapor deposition method, thereby forming an intermediate layer with an average thickness of 0.5 μm.

The porosity of the intermediate layer was 2%.

[4] An electron transport layer with an average thickness of 10 μm was formed on the intermediate layer.

First, TiO₂ particles (the average par size: 10 nm) synthesized by a sol-gel method was prepared.

Next, an ethanol aqueous solution containing the TiO₂ (inorganic semiconductor material) particles and polyethylene glycol was made.

The ethanol aqueous solution is applied onto the intermediate layer by spin coating (2000 rpm) and is then dried.

Next a collective of TiO₂ particles was baked at 450° C. for 30 minutes. Thus an electron transport layer was obtained.

The porosity of the electron transport layer was 55%.

The resistance of the deposited layer body which consists of the intermediate layer and the electron transport layer, in its thickness direction was measured. It was equal to or greater than 1 k Ω/cm².

[5] After the baked substrate was immersed in a light emitting material containing liquid (40° C.) that contains iridium complex having 2,2′-bipyridine-4,4′-carboxylic acid (light emitting material) and cholic acid for 8 hours, the substrate was cleaned subsequently with ethanol and acetonitrile.

The amount of adhesion per square centimeter of the iridium complex to the electron transport layer was set to be 1×10⁻⁸ mol.

[6] ITO was adhered onto the other lass substrate by sputtering, thereby forming an anode with an average thickness of 100 nm.

The surface resistance of the ITO electrode was about 40 Ω/cm².

[7] Water dispersions containing PEDOT/PSS (hole transfer layer material were applied onto the anode by a spin coating method (2000 rpm) and then were dried.

Thus, a second region of a hole transfer layer with an average thickness of 20 μm was formed.

[8] Two glass substrates were disposed to face each other, and the periphery was sealed with an epoxy resin. At that time, the periphery was sealed so that an inlet for injecting electrolytic composition remained.

The average thickness of the formed space was made to be 40 μm.

[9] First, I₂ and LiI as the electrolyte were solved in ethylene glycol so that an electrolytic composition in a liquid state was prepared. The concentration of the electrolyte was made to be 10 wt %.

Next, after the electrolytic composition was injected from the inlet the inlet was sealed with an epoxy resin adhesive agent.

Thus, a first region of the hole transfer layer was formed, completing the light emitting element.

### Example 2

A light emitting element was manufactured in the same manner as the above example 1 except for the above process [9], which was modified as follows.

For an electrolytic composition in a liquid state was prepared in the same manner as the above example 1.

Next, the electrolytic composition and polyethylene oxide in a molten state were mixed in the weight ratio of 5:1, whereby the mixture was obtained.

Next, after being injected from the inlet, the mixture is left at room temperature, so that the electrolytic composition turned into a gel.

### Example 3

A light emitting element was manufactured in the same manner as the above example 1 exception for the above process [9], which was modified as follows.

First, an electrolytic composition in a liquid state was prepared in the same manner as the above example 1.

Next, the electrolytic composition and a precursor of polyimide resin were mixed in the weight ratio of 5:1, whereby the mixture was obtained.

For the precursor of polyimide resin pyromellitic dianhydride and para-phenylenediamine were used in the mol ratio of 1:1.

Next, after being injected from the inlet, the mixture is heated at 120° C., so that the electrolytic composition turned into a gel.

### Example 4

A light emitting element was manufactured in the same manner as the above example 1, with the exception of using I₂ and imidazolium iodide as the electrolyte.

In the light emitting element manufactured in each example, the cathode and the anode were made positive and negative, respectively and then a 0.5 V voltage was applied to the element. The resistance was measured. The resistance was equal to or more than 1 Ω/cm² in every element.

2. Evaluation

The luminous efficiencies of the light emitting elements manufactured in the examples were evaluated.

The luminous efficiency was evaluated by applying a voltage ranging from 0 V to 6 V by a direct-current power source, measuring the current value, and measuring the brightness by a brightness photometer.

As the result from measurement, high luminous efficiency was obtained in every light emitting element of the examples. In particular the efficiency was remarkably high in the light emitting element of example 4.

What is claimed is:

1. A light emitting element, comprising:
a first electrode;
a second electrode;
an emissive layer provided between the first electrode and the second electrode; and
a carrier transporting layer provided between the first electrode and the second electrode;
wherein the carrier transporting layer includes an electrolytic composition.

2. The light emitting element as defined in claim 1, wherein the electrolyte composition is in a liquid or gel state.

3. The light emitting element as defined in claim 1, wherein the electrolytic composition contains a I/I₃-based electrolyte.

4. The light emitting element as defined in claim 1, wherein:
the carrier transporting layer includes a hole transfer layer and an electron transport layer; and
the first electrode, the hole transfer layer, the emissive layer, the electron transport layer, and the second electrode are deposited in this order.

5. The light emitting element as defined in claim 4, wherein the hole transfer layer has at a side of the first electrode a second region mainly made of a polymer material.

6. The light emitting element as defined in claim 5, wherein the second region is in contact with the first electrode.

7. The light emitting element as defined in claim 5, wherein the second region is in contact with a region made of the electrolytic composition as a main material.

8. The light emitting element as defined in claim 5, wherein the polymer material contains a polythiophene-based compound.

9. The light emitting element as defined in claim 5, wherein the hole transfer layer has an average thickness of 0.1 to 100 μm.

10. The light emitting element as defined in claim 4, wherein the electron transport layer is porous.

11. The light emitting element as defined in claim 10, further comprising an intermediate layer between the electron transport layer and the second electron.

12. The light emitting element as defined in claim 11, wherein the intermediate layer is formed so as to have a porosity smaller than the porosity of the electron transport layer.

13. The light emitting element as defined in claim 10, wherein the electron transport layer has a porosity of 20 to 75%.

14. The light emitting element as defined in claim 4, wherein the electron transport layer has an average thickness of 1 to 50 μm.

15. The light emitting element as defined in claim 4, wherein the electron transport layer is made of an inorganic semiconductor material as the main material.

16. The light emitting element as defined in claim 15, wherein the inorganic semiconductor material contains a metallic oxide as a main element.

17. The light emitting element as defined in claim 15, wherein the inorganic semiconductor material contains at least one of titanium oxide and zirconium oxide as the main element.

18. Alight emitting device, comprising the light emitting element as defined in claim 1.

19. An electronic apparatus, comprising the light emitting device as defined in claim 18.
